(19) United States
(12) Patent Application Publication
(10) Pub. No.: US 2024/0304762 A1
(43) Pub. Date: Sep. 12, 2024

(54) LIGHT-EMITTING CHIP, LIGHT-EMITTING SUBSTRATE, DISPLAY DEVICE, AND MANUFACTURING METHOD FOR LIGHT-EMITTING SUBSTRATE

(71) Applicants: BOE MLED Technology Co., Ltd., Beijing (CN); BOE Technology Group Co., Ltd., Beijing (CN)

(72) Inventors: Yutian CHU, Beijing (CN); Sha FENG, Beijing (CN); Zhijun XIONG, Beijing (CN); Yuanda LU, Beijing (CN); Liang SUN, Beijing (CN); Zhaohui LI, Beijing (CN); Enkai DONG, Beijing (CN); Jiacheng QI, Beijing (CN); Jinpeng LI, Beijing (CN); Qiqi ZHOU, Beijing (CN); Le WANG, Beijing (CN)

(21) Appl. No.: 18/026,332

(22) PCT Filed: Apr. 26, 2022
(86) PCT No.: PCT/CN2022/089318

§ 371 Date: Mar. 14, 2023

(51) Int. Cl. H01L 33/46; H01L 33/62

(52) U.S. Cl. CPC H01L 33/46; H01L 33/62; H01L 2933/0025; H01L 2933/0066

(57) ABSTRACT

Provided are a light-emitting chip, a light-emitting substrate, a display device, and a manufacturing method for a light-emitting substrate. The light-emitting chip includes: a substrate; a light-emitting structure, the light-emitting structure disposed on a side of the substrate; a reflective layer disposed on a side, facing away from the substrate, of the light-emitting structure; at least two sub-light-emitting auxiliary bonding layers disposed on a side, facing away from the light-emitting structure, of the reflective layer; and a raised portion, disposed on a side, facing away from the light-emitting structure, of the reflective layer, an orthographic projection of the raised portion on the substrate and an orthographic projection of the sub-light-emitting auxiliary bonding layers on the substrate do not overlap with each other, and a thickness of the raised portion is smaller than a thickness of each of the at least two sub-light-emitting auxiliary bonding layers.

### FIELD

The present disclosure relates to the technical field of semiconductors, and in particular to a light-emitting chip, a light-emitting substrate, a display device, and a manufacturing method for a light-emitting substrate.

### BACKGROUND

Light-emitting diode (LED) display refers to a technology of arraying and miniaturizing a vast number of traditional LEDs, addressing the LEDs, and transferring the LEDs to a circuit substrate, so as to form an LED display panel minimally spaced, and further miniaturizing a size of the LEDs to the micron grade, so as to achieve ultra-high pixels and ultra-high resolution, thereby being adaptable to screens of various sizes theoretically. Generally, the LEDs employ an epitaxial growth process. Matrices include sapphire, monocrystalline silicon, silicon carbide, etc. Compared with organic light-emitting display and liquid crystal display, the LED display features a higher light efficiency, a better display effect, and a lower power, and thus has become a research hotspot in display industry.

### SUMMARY

The present disclosure provides a light-emitting chip, a light-emitting substrate, a display device, and a manufacturing method for a light-emitting substrate. The light-emitting chip includes:
a substrate;
a light-emitting structure, the light-emitting structure disposed on a side of the substrate;
a reflective layer, the reflective layer disposed on a side, facing away from the substrate, of the light-emitting structure;
at least two sub-light-emitting auxiliary bonding layers, the at least two sub-light-emitting auxiliary bonding layers disposed on a side, facing away from the light-emitting structure, of the reflective layer; and
a raised portion, the raised portion disposed on a side, facing away from the light-emitting structure, of the reflective layer;
where an orthographic projection of the raised portion on the substrate and an orthographic projection of the at least two sub-light-emitting auxiliary bonding layers on the substrate do not overlap with each other; and
a thickness of the raised portion is smaller than a thickness of each of the at least two sub-light-emitting auxiliary bonding layers.

In some embodiments, the light-emitting structure includes a first semiconductor layer, a light-emitting layer, and a second semiconductor layer;
the first semiconductor layer, the light-emitting layer, and the second semiconductor layer are sequentially stacked on a side of the substrate; and
an orthographic projection, on the substrate, of at least one of the first semiconductor layer, the light-emitting layer, and the second semiconductor layer substantially approximately overlaps with an orthographic projection, on the substrate, of the raised portion, so as to form the raised portion.

In some embodiments, a thickness of the reflective layer in a region where the raised portion is located is approximately equal to a thickness of the reflective layer in a region where the sub-light-emitting auxiliary bonding layers is located.

In some embodiments, the light-emitting chip is a light-emitting chip emitting red light, the first semiconductor layer is a P-type semiconductor layer, and the second semiconductor layer is an N-type semiconductor layer; and
the raised portion of the light-emitting chip is formed by the second semiconductor laver.

In some embodiments, a thickness of the reflective layer in the region where the raised portion is located is greater than a thickness of the reflective layer in the region where the sub-light-emitting auxiliary bonding layer is located, so as to form the raised portion by thickening the region, where the raised portion is positioned, of the reflective layer.

In some embodiments, the raised portion and the reflective layer are of an integrated structure; and the raised portion is made of a same material as the reflective layer.

In some embodiments, the raised portion and the reflective layer are of structures independent of each other, and the raised portion is made of a different material from the reflective layer.

In some embodiments, the light-emitting chip is a light-emitting chip emitting blue light or green light; and
the first semiconductor layer is an N-type semiconductor layer, and the second semiconductor layer is a P-type semiconductor layer.

An embodiment of the present disclosure further provides a light-emitting substrate. The light-emitting substrate includes the light-emitting chip according to the embodiment of the present disclosure, and further includes a circuit substrate, where the circuit substrate includes a plurality of sub-substrate pads, the sub-substrate pads are soldered to the sub-light-emitting auxiliary bonding layers in a one-to-one corresponding manner.

In some embodiments, the circuit substrate is provided with a substrate bulge between adjacent sub-substrate pads, the substrate bulge making contact with the raised portion.

In some embodiments, the circuit substrate is provided with a plurality of recessed regions in regions where the sub-substrate pads are located.

An embodiment of the present disclosure further provides a display device. The display device includes the light-emitting substrate according to the embodiment of the present disclosure.

An embodiment of the present disclosure further provides a manufacturing method for the light-emitting substrate according to the embodiment of the present disclosure. The method includes:
forming the light-emitting chip, the light-emitting chip including the plurality of sub-light-emitting auxiliary bonding layers and the raised portion located between adjacent sub-light-emitting auxiliary bonding layers;
providing the circuit substrate, the circuit substrate including the plurality of sub-substrate pads and the substrate bulge located between adjacent sub-substrate pads; and
soldering the sub-light-emitting auxiliary bonding layers of the light-emitting chip to the sub-substrate pads of the circuit substrate in a one-to-one corresponding manner, and making the substrate bulge be in lap joint with the raised portion.

In some embodiments, the forming a light-emitting chip includes:
forming an N-type semiconductor layer, a light-emitting layer, and a P-type semiconductor layer on a side of an initial substrate;
forming the substrate on a side, facing away from the light-emitting layer, of the P-type semiconductor layer;
removing the initial substrate;
etching and removing a portion, outside a region between adjacent sub-light-emitting auxiliary bonding layers, of the P-type semiconductor layer;
forming the reflective layer on a side, facing away from the light-emitting layer, of the P-type semiconductor layer, so that the reflective layer bulges in a region where a remaining P-type semiconductor layer is located, to form the raised portion; and
forming the plurality of sub-light-emitting auxiliary bonding layers.

In some embodiments, the forming a light-emitting chip includes:
forming an N-type semiconductor layer, a light-emitting layer, a P-type semiconductor layer, and a reflective layer, sequentially on a side of the substrate;
etching a portion of the reflective layer in a region where the sub-light-emitting auxiliary bonding layers is located, where a thickness of the reflective layer in the region between adjacent sub-light-emitting auxiliary bonding layers is greater than a thickness of the reflective layer in the region where the sub-light-emitting auxiliary bonding layer is located, and the reflective layer in the region between the adjacent sub-light-emitting auxiliary bonding layers forms the raised portion; and
forming the plurality of sub-light-emitting auxiliary bonding layers.

In some embodiments, the forming a light-emitting chip includes:
forming an N-type semiconductor layer, a light-emitting layer, a P-type semiconductor layer, and a reflective layer, sequentially on a side of the substrate;
forming the raised portion in a region between adjacent sub-light-emitting auxiliary bonding layers on a side, facing away from the P-type semiconductor layer, of the reflective layer; and
forming the plurality of sub-light-emitting auxiliary bonding layers.

### BRIEF DESCRIPTION OF THE DRAWINGS

FIG. 1 is a schematic structural diagram of a conventional light-emitting chip not soldered to a circuit substrate.

FIG. 2 is a schematic structural diagram of a conventional light-emitting chip soldered to a circuit substrate.

FIG. 3 is a schematic diagram of a conventional light-emitting chip not soldered to a circuit substrate completely.

FIG. 4A is a first schematic sectional view of a light-emitting chip according to an embodiment of the present disclosure.

FIG. 4B is a second schematic sectional view of a light-emitting chip according to an embodiment of the present disclosure.

FIG. 4C is a third schematic sectional view of a light-emitting chip according to an embodiment of the present disclosure.

FIG. 5 is a first schematic top view of a light-emitting chip according to an embodiment of the present disclosure.

FIG. 6 is a fourth schematic sectional view of a light-emitting chip according to an embodiment of the present disclosure.

FIG. 7 is a second schematic top view of a light-emitting chip according to an embodiment of the present disclosure.

FIG. 8 is a fifth schematic sectional view of a light-emitting chip according to an embodiment of the present disclosure.

FIG. 9 is a sixth schematic sectional view of a light-emitting chip according to an embodiment of the present disclosure.

FIG. 10 is a third schematic top view of a light-emitting chip according to an embodiment of the present disclosure.

FIG. 11 is a schematic top view of a light-emitting chip soldered to a circuit substrate according to an embodiment of the present disclosure.

FIG. 12 is a first schematic diagram of a manufacturing process for a light-emitting substrate according to an embodiment of the present disclosure.

FIG. 13 is a second schematic diagram of a manufacturing process for a light-emitting substrate according to an embodiment of the present disclosure.

FIG. 14 is a third schematic diagram of a manufacturing process for a light-emitting substrate according to an embodiment of the present disclosure.

FIG. 15 is a fourth schematic diagram of a manufacturing process for a light-emitting substrate according to an embodiment of the present disclosure.

FIG. 16A is a schematic sectional view of a light-emitting chip emitting red light in the case of forming a second semiconductor layer according to an embodiment of the present disclosure.

FIG. 16B is a schematic sectional view of a light-emitting chip emitting red light in the case of forming a light-emitting layer according to an embodiment of the present disclosure.

FIG. 16C is a schematic sectional view of a light-emitting chip emitting red light in the case of forming a first semiconductor layer according to an embodiment of the present disclosure.

FIG. 16D is a schematic sectional view of a light-emitting chip emitting red light in the case of forming a substrate according to an embodiment of the present disclosure.

FIG. 16E is a schematic sectional view of a light-emitting chip emitting red light in the case of removing an initial substrate according to an embodiment of the present disclosure.

FIG. 16F is a schematic sectional view of a light-emitting chip emitting red light in the case of forming a second patterned semiconductor layer according to an embodiment of the present disclosure.

FIG. 16G is a schematic sectional view of a light-emitting chip emitting red light in the case of forming a reflective layer according to an embodiment of the present disclosure.

FIG. 16H is a schematic sectional view of a light-emitting chip emitting red light in the case of forming a sub-light-emitting auxiliary bonding layers according to an embodiment of the present disclosure.

FIG. 16I is a schematic sectional view of a light-emitting chip emitting red light soldered to a circuit substrate according to an embodiment of the present disclosure.

FIG. 16J shows a curve of an ABC model of an internal quantum efficiency of a light-emitting diode (LED).

FIG. 17A is a schematic sectional view of a light-emitting chip emitting blue light or green light in the case of forming a first semiconductor layer according to an embodiment of the present disclosure.

FIG. 17B is a schematic sectional view of a light-emitting chip emitting blue light or green light in the case of forming a light-emitting layer according to an embodiment of the present disclosure.

FIG. 17C is a schematic sectional view of a light-emitting chip emitting blue light or green light in the case of forming a second semiconductor layer according to an embodiment of the present disclosure.

FIG. 17D is a schematic sectional view of a light-emitting chip emitting blue light or green light in the case of forming a reflective layer according to an embodiment of the present disclosure.

FIG. 17E is a schematic sectional view of a light-emitting chip emitting blue light or green light after a reflective layer is patterned according to an embodiment of the present disclosure.

FIG. 17F is a schematic sectional view of a light-emitting chip emitting blue light or green light after a sub-light-emitting auxiliary bonding layers is formed on a reflective layer according to an embodiment of the present disclosure.

FIG. 17G is a schematic sectional view of a light-emitting chip emitting blue light or green light soldered to a circuit substrate according to an embodiment of the present disclosure.

FIG. 18A is a schematic sectional view of another light-emitting chip emitting blue light or green light in the case of forming a first semiconductor layer according to an embodiment of the present disclosure.

FIG. 18B is a schematic sectional view of another light-emitting chip emitting blue light or green light in the case of forming a light-emitting layer according to an embodiment of the present disclosure.

FIG. 18C is a schematic sectional view of another light-emitting chip emitting blue light or green light in the case of forming a second semiconductor layer according to an embodiment of the present disclosure.

FIG. 18D is a schematic sectional view of another light-emitting chip emitting blue light or green light in the case of forming a reflective layer according to an embodiment of the present disclosure.

FIG. 18E is a schematic sectional view of another light-emitting chip emitting blue light or green light in the case of forming a raised portion 30 according to an embodiment of the present disclosure.

FIG. 18F is a schematic sectional view of another light-emitting chip emitting blue light or green light after a sub-light-emitting auxiliary bonding layers is formed according to an embodiment of the present disclosure.

FIG. 18G is a schematic sectional view of another light-emitting chip emitting blue light or green light soldered to a circuit substrate according to an embodiment of the present disclosure.

### DETAILED DESCRIPTION OF THE EMBODIMENTS

In order to make the objectives, technical solutions, and advantages in embodiments of the present disclosure clearer, the technical solutions in embodiments of the present disclosure will be clearly and completely described below in combination with the accompanying drawings in embodiments of the present disclosure. It is obvious that the described embodiments are some embodiments rather than all embodiments of the present disclosure. Based on the described embodiments of the present disclosure, all other embodiments obtained by a person of ordinary skill in the art without making inventive efforts fall within the scope of protection of the present disclosure.

Unless defined otherwise, technical or scientific terms used in the present disclosure should be of ordinary meaning as understood by a person of ordinary skill in the art to which the present disclosure pertains. Words “first”, “second”, etc. used in the present disclosure do not denote any order, quantity, or importance, but are merely used to distinguish between different components. Words “comprising”, “encompass” or the like is intended to mean that an element or item in front of the word encompasses elements or items behind the word and equivalents thereof, but do not exclude other elements or items. Words “connection”, “connected” or the like is not limited to physical or mechanical connections, but can include an electrical connection, whether direct or indirect. “Upper”, “lower”, “left”, “right”, etc. are merely used to indicate a relative position relation, which may also change accordingly when an absolute position of a described object changes.

In order to keep the following description of the embodiments of the present disclosure clear and concise, the detailed descriptions of known functions and components are omitted from the present disclosure.

Most mini light-emitting diodes and/or micro light-emitting diodes employ a flip mode. Solder is pre-prepared on bulges/a bulge of the mini light-emitting diode and/or the micro light-emitting diode, and a quantitative soldering flux is pre-prepared on a substrate pad. After the mini light-emitting diode and/or the micro light-emitting diode are/is transferred to the substrate pad through a mass transfer technology, the solder on the bulges/the bulge of the mini light-emitting diode and/or the micro light-emitting diode makes contact with the substrate pad under the action of the soldering flux. Then the mini light-emitting diode and/or the micro light-emitting diode and the substrate pad pass through a reflow oven, and are heated in a high-temperature area, so as to melt the solder on the bulges/the bulge of the mini light-emitting diode and/or the micro light-emitting diode. Finally, the mini light-emitting diode and/or the micro light-emitting diode and the substrate pad pass through a cooling area for cooling, so as to solidify the solder. Through this process, the substrate pad and the mini light-emitting diode and/or the micro light-emitting diode are bonded together, so as to realize electrical connection.

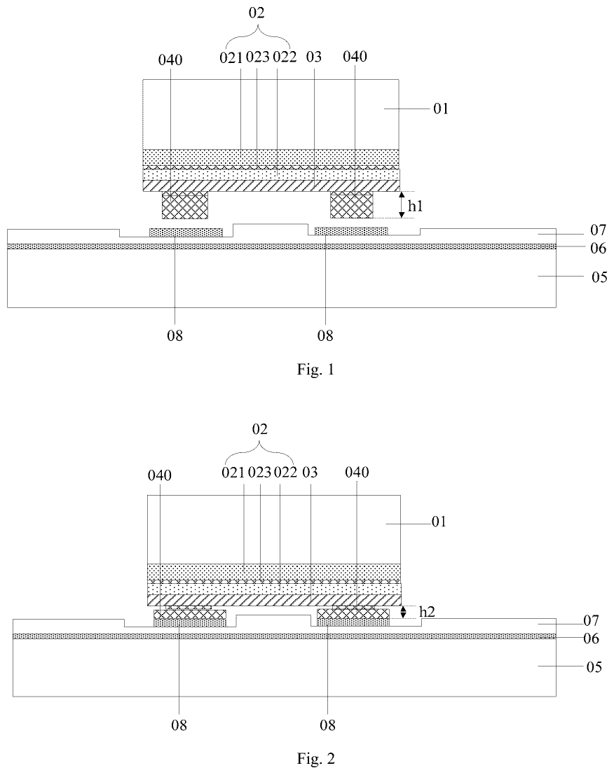

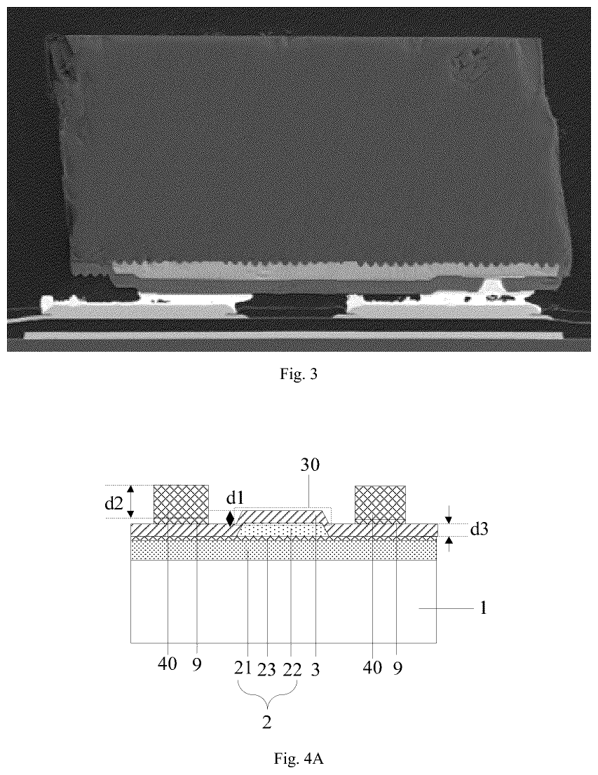

In some embodiments, as shown in FIGS. 1 and 2, the mini light-emitting diode and/or the micro light-emitting diode include/includes: a substrate 01, and a light-emitting structure 02 (which may include a first semiconductor layer 021, a light-emitting layer 023, and a second semiconductor layer 022 sequentially stacked), and a reflective layer 03 sequentially disposed on a side of the substrate 01. The solder 040 of the mini light-emitting diode and/or the micro light-emitting diode has a thickness of h1, that is, a height difference between the reflective layer 03 and the solder 040 is h1. A circuit substrate includes a circuit substrate 05, and a conductive layer 06, an insulation layer 07, and a plurality of sub-substrate pads 08 sequentially disposed on a side of the circuit substrate 05. The mini light-emitting diode and/or the micro light-emitting diode are/is transferred onto the substrate pad, and heated through the reflow oven, so that the solder 040 is melted and wet, and spreads over the substrate pad. As shown in FIG. 2, the solder and the substrate pad are bonded together through reflow soldering. In this case, the reflective layers/reflective layer 03 of the mini light-emitting diode and/or the micro light-emitting diode have/has a thickness of h2, h2<h1. Since the solder 040 is melted and spreads over the substrate pad, the height is reduced. Moreover, solder at a soldering position is discontinuous (as shown in the whitest region in FIG. 3), so that a final thickness of a solder joint is difficult to control, thereby affecting a soldering yield.

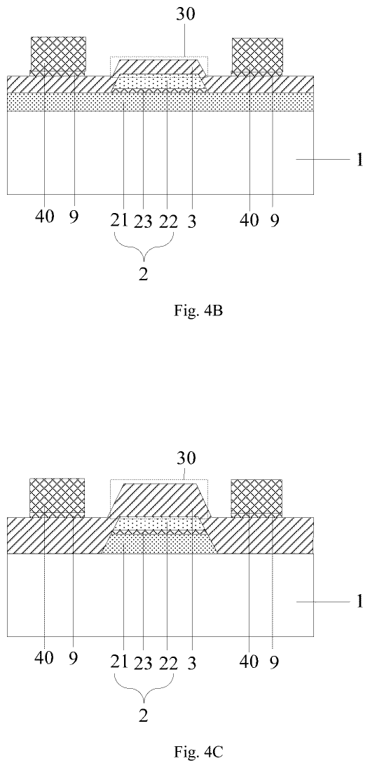

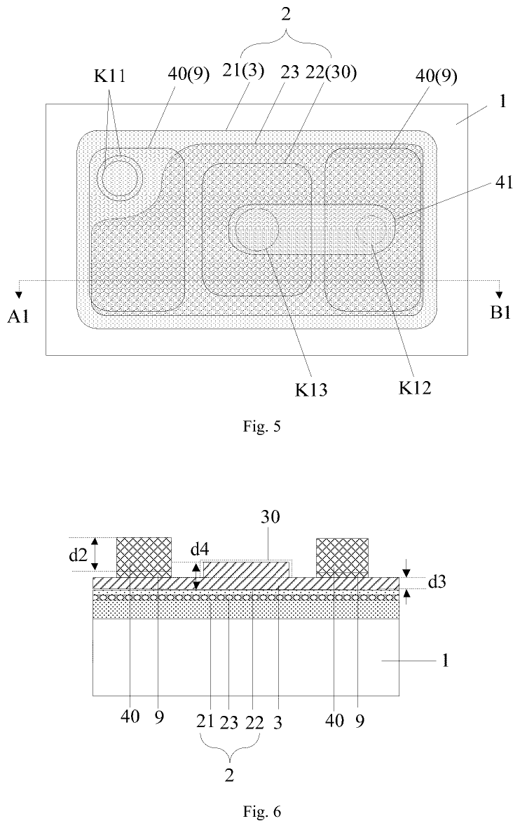

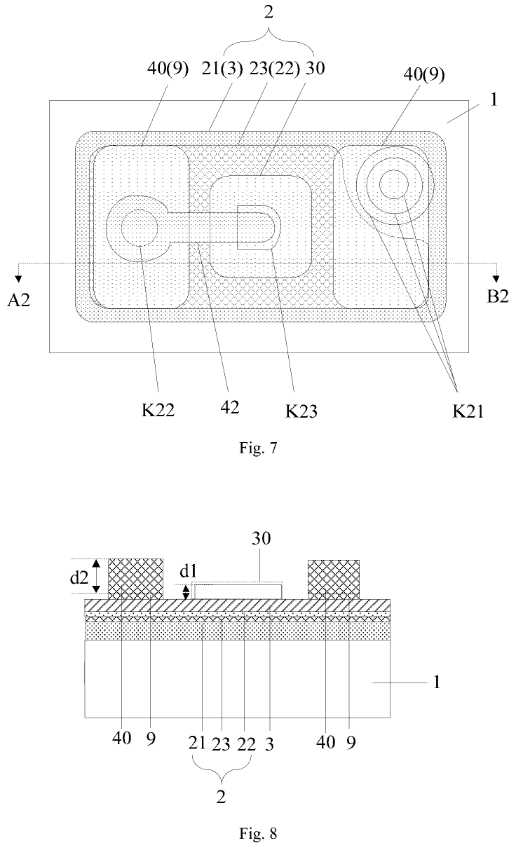

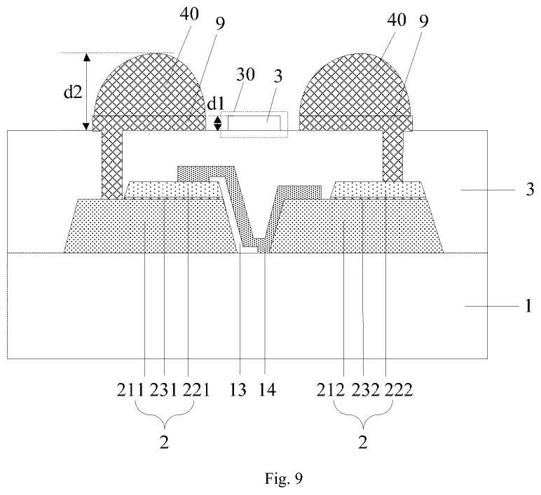

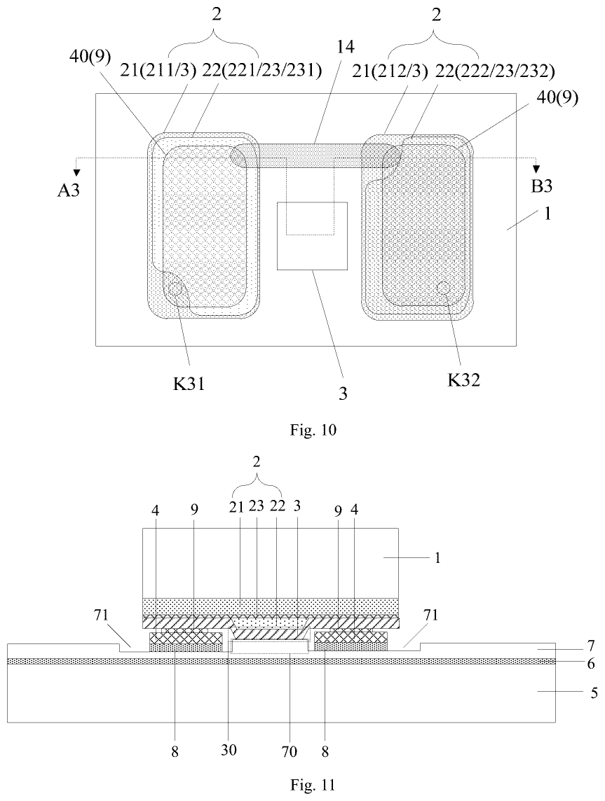

In view of this, reference is made to FIGS. 4A to 10, where FIG. 4A is a schematic sectional view at A1B1 in FIG. 5, FIG. 6 is a schematic sectional view at A2B2 in FIG. 7, FIG. 8 is another schematic sectional view at A2B2 in FIG. 7, and FIG. 9 is a schematic sectional view at A3B3 in FIG. 10. An embodiment of the present disclosure provides a light-emitting chip. The light-emitting chip includes:
a substrate 1;
a light-emitting structure 2, the light-emitting structure 2 disposed on a side of the substrate 1;
a reflective layer 3, the reflective layer 3 disposed on a side, facing away from the substrate 1, of the light-emitting structure 2;
at least two sub-light-emitting auxiliary bonding layers 40, the at least two sub-light-emitting auxiliary bonding layers 40 disposed on a side, facing away from the light-emitting structure 2, of the reflective layer 3, where the sub-light-emitting auxiliary bonding layers 40 may be solder, and the sub-light-emitting auxiliary bonding layers 40 may be melted when the light-emitting chip is soldered to a circuit substrate; and
a raised portion 30, the raised portion 30 disposed on a side, facing away from the light-emitting structure 2, of the reflective layer 3, an orthographic projection of the raised portion 30 on the substrate 1 and an orthographic projection of the sub-light-emitting auxiliary bonding layers 40 on the substrate 1 do not overlap with each other, and a thickness d1 of the raised portion 30 is smaller than a thickness d2 of each of the sub-light-emitting auxiliary bonding layers 40.

In the embodiment of the present disclosure, the light-emitting chip includes the raised portion 30, the orthographic projection of the raised portion 30 on the substrate 1 and an orthographic projection of the sub-light-emitting auxiliary bonding layers 40 on the substrate 1 do not overlap with each other, and a thickness d1 of the raised portion 30 is smaller than a thickness d2 of each of the sub-light-emitting auxiliary bonding layers 40. When the light-emitting chip is soldered to the circuit substrate, the raised portion 30 may be in lap joint with the circuit substrate to fix a distance between the light-emitting chip and the circuit substrate. Therefore, a final thickness of a solder joint may be controlled, and the fixed thickness of the solder joint may increase the tension when the sub-light-emitting auxiliary bonding layers 40 is melted, so that the solder formed by melting the sub-light-emitting auxiliary bonding layers 40 is continuously and uniformly stretched, thereby increasing a soldering yield of the light-emitting chip and the circuit substrate. If the light-emitting chip is soldered to the circuit substrate poorly, the raised portion 30 is arranged to form a large distance between the light-emitting chip and the circuit substrate, so that the damage to a sub-substrate pad 8 is avoided when the light-emitting chip is separated from the circuit substrate, and a repair yield may also be increased. Moreover, since the raised portion 30 exists between the sub-light-emitting auxiliary bonding layers 40, the problem that the light-emitting chip fails due to the fact that different sub-light-emitting auxiliary bonding layers 40 are electrically connected during soldering when the distance between the sub-light-emitting auxiliary bonding layers 40 is small may be prevented. In addition, considering that an area of the sub-substrate pad will be correspondingly expanded in actual use, so as to adapt to the design of mini light-emitting diodes and/or micro light-emitting diodes with different size. For the small-sized mini light-emitting diode and/or micro light-emitting diode, the sub-light-emitting auxiliary bonding layers 40 is small and spreads over the sub-substrate pad with a large area after reflow, and the thickness of the solder joint will be correspondingly reduced. If the raised portion 30 in the embodiment of the present disclosure is provided, the thickness of the solder joint will not be reduced excessively. Therefore, in one aspect, the requirement on the amount of the solder and the area accuracy of the sub-substrate pad may be reduced, and in another aspect, the sub-substrate pad with the same size may be adapted to mini light-emitting diodes and/or micro light-emitting diodes with various specifications, so that the compatibility is high.

In some embodiments, a light-emitting electrode 9 is further provided between the sub-light-emitting auxiliary bonding layers 40 and the reflective layer 3, and the sub-light-emitting auxiliary bonding layers 40 may be formed on a surface of one side, facing away from the reflective layer 3, of the light-emitting electrode 9 before the light-emitting chip is soldered to the circuit substrate. In some embodiments, the relation between an area of the orthographic projection, on the substrate 1, of the sub-light-emitting auxiliary bonding layers 40 and an area of an orthographic projection, on the substrate 1, of the light-emitting electrode 9 is not particularly limited. In some embodiments, the area of the orthographic projection, on the substrate 1, of the sub-light-emitting auxiliary bonding layers 40 may be equal to the area of the orthographic projection, on the substrate 1, of the light-emitting electrode 9, and the orthographic projection, on the substrate 1, of the sub-light-emitting auxiliary bonding layers 40 may overlap the orthographic projection, on the substrate 1, of the light-emitting electrode 9. In some embodiments, the area of the orthographic projection, on the substrate 1, of the sub-light-emitting auxiliary bonding layers 40 may be smaller than the area of the orthographic projection, on the substrate 1, of the light-emitting electrode 9, and the orthographic projection on the substrate 1, of the light-emitting electrode 9 covers the orthographic projection, on the substrate 1, of the sub-light-emitting auxiliary bonding layers 40.

In some embodiments, as shown in FIGS. 4A, 6, 8, and 9, the light-emitting structure 2 includes a first semiconductor layer 21, a light-emitting layer 23, and a second semiconductor layer 22 sequentially stacked on one side of the substrate 1. In some embodiments, the light-emitting chip may be a light-emitting chip emitting red light, when the light-emitting chip is a light-emitting chip emitting red light, the first semiconductor layer 21 may be a P-type semiconductor layer, and the second semiconductor layer 22 may be an N-type semiconductor layer.

In some embodiments, as shown in FIGS. 4A, 4B, and 4C, the light-emitting structure 2 includes a first semiconductor layer 21, a light-emitting layer 23, and a second semiconductor layer 22 sequentially stacked on one side of the substrate 1. An orthographic projection, on the substrate 1, of at least one of the first semiconductor layer 21, the light-emitting layer 23, and the second semiconductor layer 22 substantially overlaps an orthographic projection, on the substrate 1, of the raised portion 30, so as to form the raised portion 30. In some embodiments, a portion, in a region with the sub-light-emitting auxiliary bonding layers 40, of at least one of the first semiconductor layer 21, the light-emitting layer 23, and the second semiconductor layer 22 may be etched and removed or thinned, so that a total thickness of a film layer of portions, in regions without the sub-light-emitting auxiliary bonding layers 40, of the first semiconductor layer 21, the light-emitting layer 23, and the second semiconductor layer 22 is greater than a total thickness of a film layer of the portion, in the region where the sub-light-emitting auxiliary bonding layers 40 is positioned, of the first semiconductor layer 21, the light-emitting layer 23, and the second semiconductor layer 22. Therefore, when the reflective layer 3 is finally formed, a bulge may be formed on a portion, in a region without the sub-light-emitting auxiliary bonding layers 40, of the reflective layer 3, so as to form the corresponding raised portion 30.

In some embodiments, the first semiconductor layer 21 may be the P-type semiconductor layer, and the second semiconductor layer 22 may be the N-type semiconductor layer. In some embodiments, the first semiconductor layer 21 may also be the N-type semiconductor layer, and the second semiconductor layer 22 may also be the P-type semiconductor layer. The light-emitting layer 23 may be a multiple quantum well (MQW) layer.

In some embodiments, in the case of etching or thinning at least one of the first semiconductor layer 21, the light-emitting layer 23, and the second semiconductor layer 22, so as to form the raised portion 30 in the portion, in a remaining region, of the reflective layer 3. As shown in FIG. 4A, a thickness d1, in a region where the raised portion 30 is positioned, of the reflective layer 3 is substantially the same as a thickness d3, in the region where the sub-light-emitting auxiliary bonding layers 40 is positioned, of the reflective layer 3. It can be understood that in an actual technological manufacturing process, it is technologically difficult to require that the thickness d1, in the region where the raised portion 30 is positioned, of the reflective layer 3 is completely the same as the thickness d3, in the region where the sub-light-emitting auxiliary bonding layers 40 is positioned, of the reflective layer 3. Therefore, in the embodiment of the present disclosure, the thickness d1, in the region where the raised portion 30 is positioned, of the reflective layer 3 is substantially the same as the thickness d3, in the region where the sub-light-emitting auxiliary bonding layers 40 is positioned, of the reflective layer 3. It may be understood that a ratio of a difference between two cases to any one of the two thicknesses is less than 10%.

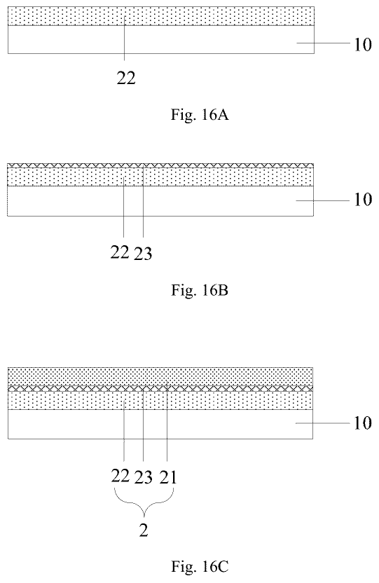

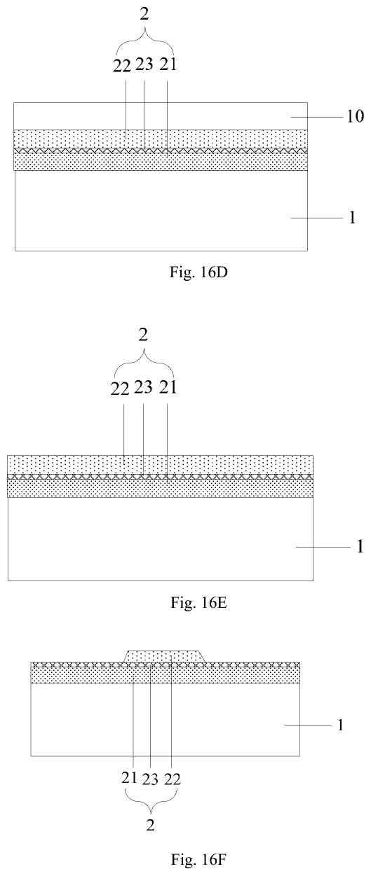

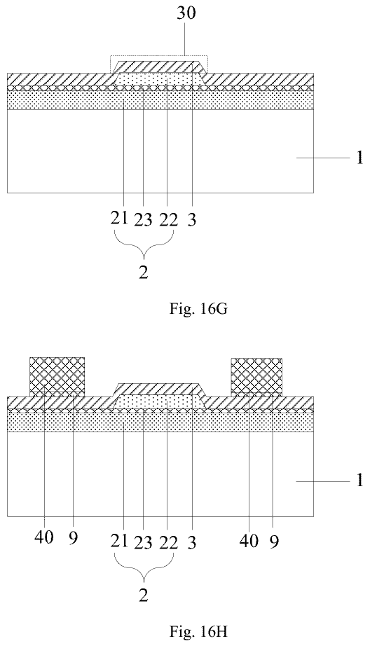

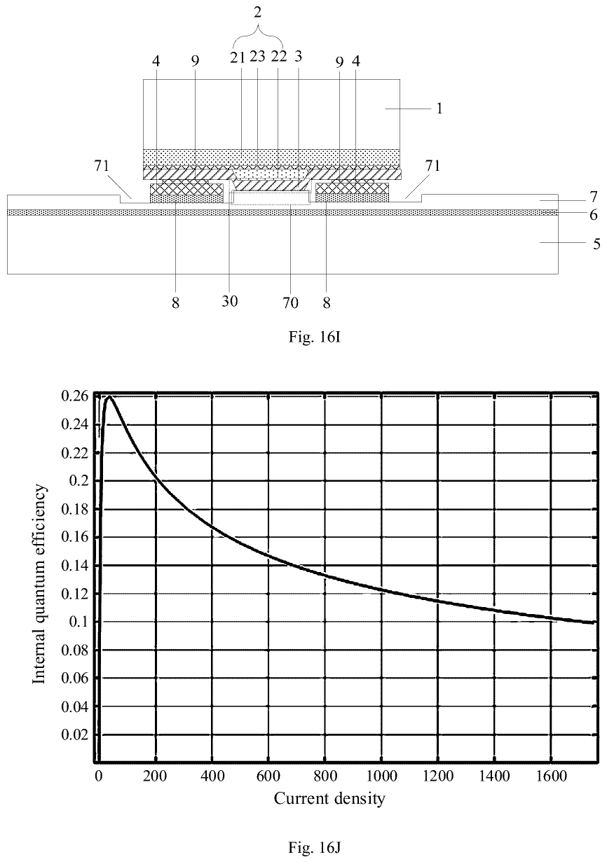

In some embodiments, as shown in FIG. 4A, the light-emitting chip is a light-emitting chip emitting red light, the first semiconductor layer 21 is the P-type semiconductor layer, and the second semiconductor layer 22 is the N-type semiconductor layer. The raised portion 30 is formed through the second semiconductor layer 22 for the light-emitting chip. In the embodiment of the present disclosure, for the light-emitting chip emitting red light, due to the limitation of materials, the N-type semiconductor layer is generally positioned on one side, away from the substrate 1, of the P-type semiconductor layer. During specific manufacturing, as shown in FIGS. 16A to 16I, the N-type semiconductor layer (as the second semiconductor layer 22), the light-emitting layer 23, the P-type semiconductor layer (as the first semiconductor layer 21), and a buffer layer 24 may be sequentially formed on an initial substrate. The initial substrate on which the N-type semiconductor layer (as the second semiconductor layer 22), the light-emitting layer 23, the P-type semiconductor layer (as the first semiconductor layer 21), and the buffer layer 24 are formed is bonded to the substrate 1. Then the initial substrate is removed, and the reflective layer 3 is formed. Finally, the sub-light-emitting auxiliary bonding layers 40 are formed. The process of sequentially forming the N-type semiconductor layer (as the second semiconductor layer 22), the light-emitting layer 23, the P-type semiconductor layer (as the first semiconductor layer 21), and the buffer layer 24 on the initial substrate is performed in a high-temperature environment. If the light-emitting layer 23 or the P-type semiconductor layer (as the first semiconductor layer 21) is required to be etched and thinned, the initial substrate is required to be taken out of the high-temperature environment, and then enters the high-temperature environment to continue subsequent processes after etching is completed, so that the problem that it is difficult to control the thermal stress and the temperature to be consistent is caused. However, by etching and patterning the N-type semiconductor layer (as the second semiconductor layer 22), it is not required to take out the N-type semiconductor layer from the high temperature environment, so that the problem that it is difficult to control the thermal stress and the temperature to be consistent is not caused, that is, for the light-emitting chip emitting red light, it is easier to etch and pattern the second semiconductor layer 22, and to form the raised portion 30.

In some embodiments, for the light-emitting chip emitting red light, the first semiconductor layer 21 is the P-type semiconductor layer, and the second semiconductor layer 22 is the N-type semiconductor layer. A structure of the raised portion 30 is formed through the second semiconductor layer 22 for the light-emitting chip. As shown in FIG. 5, the light-emitting layer 23 may be provided with a missing region (a missing region at the upper left corner of the light-emitting layer 23 in FIG. 5) exposing the first semiconductor layer 21. One light-emitting electrode 9 (the light-emitting electrode 9 on the left side in FIG. 5) may be connected to the first semiconductor layer 21 through a first via hole K11 penetrating the reflective layer 3 in the missing region, so as to lead out the first semiconductor layer 21 through one light-emitting electrode 9. The other light-emitting electrode 9 (the light-emitting electrode 9 on the right side in FIG. 5) may be electrically connected to one side (the right side in FIG. 5) of a first connection electrode 41 through the second via hole K12, and the other side (the left side in FIG. 5) of the first connection electrode 41 may be electrically connected to the second semiconductor layer 22 through a third via hole K13, so as to lead out the second semiconductor layer 22 through the other light-emitting electrode 9.

In some embodiments, as shown in FIG. 6, a thickness d4 of a portion, in a region where the raised portion 30 is positioned, of the reflective layer 3 is greater than the thickness d3 of the portion, in the region where the sub-light-emitting auxiliary bonding layers 40 is positioned, of the reflective layer 3, so that the raised portion 30 is formed by thickening the portion, in the region where the raised portion 30 is positioned, of the reflective layer 3. In some embodiments, a thick reflective layer 3 may be formed firstly. Then the portion, in the region where the sub-light-emitting auxiliary bonding layers 40 are positioned, of the reflective layer 30 is thinned. Therefore, the portion, in the region without the sub-light-emitting auxiliary bonding layers 40, of the reflective layer 3 has a greater thickness than the portion, in the region where the sub-light-emitting auxiliary bonding layers 40 is provided, of the reflective layer 3, thereby forming the raised portion 30.

In some embodiments, the light-emitting chip shown in FIGS. 6 and 7 may be a light-emitting chip emitting blue light or green light. The first semiconductor layer 21 is the N-type semiconductor layer, and the second semiconductor layer 22 is the P-type semiconductor layer. As shown in FIG. 7, the light-emitting layer 23 may be provided with a missing region (a missing region at the lower right corner of the light-emitting layer 23 in FIG. 7) exposing the first semiconductor layer 21. One light-emitting electrode 9 (the light-emitting electrode 9 on the right side in FIG. 5) may be connected to the first semiconductor layer 21 through a fourth via hole K21 in the missing region, so as to lead out the first semiconductor layer 21 through one light-emitting electrode 9. The other light-emitting electrode 9 (the light-emitting electrode 9 on the left side in FIG. 7) may be electrically connected to one side (the left side in FIG. 7) of a second connection electrode 42 through a fifth via hole K22, and the other side (the right side in FIG. 7) of the second connection electrode 42 may be electrically connected to the second semiconductor layer 22 through a sixth via hole K23, so as to lead out the second semiconductor layer 22 through the other light-emitting electrode 9.

In some embodiments, as shown in FIG. 4A or 6, the raised portion 30 and the reflective layer 3 are of an integrated structure; and the raised portion 30 is made of the same material as the reflective layer 3.

In some embodiments, as shown in FIG. 8 or 9, the raised portion 30 and the reflective layer 3 are of structures independent of each other; and the raised portion 30 is made of a different material from the reflective layer 3. In some embodiments, after the reflective layer 3 is formed, a patterned structure may be formed on a portion without the sub-light-emitting auxiliary bonding layers 40 on one side, facing away from the second semiconductor layer 22, of the reflective layer 3, and the patterned structure is used as the raised portion 30.

In some embodiments, the reflective layer 3 may be a structure formed by alternately stacking a first reflective sub-layer and a second reflective sub-layer. In some embodiments, for example, the first reflective sub-layer may be made of silicon dioxide, the second reflective sub-layer may be made of titanium dioxide, and the reflective layer 3 formed by alternately stacking the first reflective sub-layer and the second reflective sub-layer may play a role of Bragg reflection. Only a film layer made of the same material as the first reflective sub-layer may be used for forming the raised portion 30, so as to only control the thickness of the raised portion 30, instead of playing a role of Bragg reflection.

In some embodiments, as shown in FIGS. 4A to 8, the light-emitting chip may include one first semiconductor layer 21, one light-emitting layer 23, and one second semiconductor layer 22. In some embodiments, as shown in FIGS. 9 and 10, the light-emitting chip may be a high-voltage chip, and may include two first semiconductor layers 21 (a first semiconductor sub-layer 211 and a second semiconductor sub-layer 212, respectively), two light-emitting layers 23 (a first light-emitting sub-layer 231 and a second light-emitting sub-layer 232, respectively), and two second semiconductor layers 22 (a third semiconductor sub-layer 221 and a fourth semiconductor sub-layer 222, respectively). An orthographic projection, on the substrate 1, of the first semiconductor sub-layer 211, an orthographic projection, on the substrate 1, of the first light-emitting sub-layer 231, and an orthographic projection, on the substrate 1, of the third semiconductor sub-layer 221 overlap to form one light-emitting structure. An orthographic projection, on the substrate 1, of the second semiconductor sub-layer 212, an orthographic projection, on the substrate 1, of the second light-emitting sub-layer 232, and an orthographic projection, on the substrate 1, of the fourth semiconductor sub-layer 222 overlap to form the other light-emitting structure. The two light-emitting structures are electrically connected to each other through a third bridge electrode 14. In some embodiments, an insulation layer 13 is further formed between the third bridge electrode 14 and sidewalls of the first semiconductor sub-layer 211, the first light-emitting sub-layer 231, the third semiconductor sub-layer 221, and the fourth semiconductor sub-layer 222.

In some embodiments, for the high-voltage chip shown in FIGS. 9 and 10, the light-emitting chip may include two first semiconductor layers 21 (the first semiconductor sub-layer 211 and the second semiconductor sub-layer 212, respectively), two light-emitting layers 23 (the first light-emitting sub-layer 231 and the second light-emitting sub-layer 232, respectively), and two second semiconductor layers 22 (the third semiconductor sub-layer 221 and the fourth semiconductor sub-layer 222, respectively). The first semiconductor layer 21 may be the N-type semiconductor layer, and the second semiconductor layer 22 may be the P-type semiconductor layer. As shown in FIGS. 9 and 10, the first light-emitting sub-layer 231 and the third semiconductor sub-layer 221 may be provided with a missing region (a missing region at the lower left corner of the first light-emitting sub-layer 231 in FIG. 10) exposing the first semiconductor sub-layer 211. One light-emitting electrode 9 (the light-emitting electrode 9 on the left side in FIG. 10) may be electrically connected to the first semiconductor sub-layer 211 through a seventh via hole K31, so as to lead out the first semiconductor sub-layer 211 through one light-emitting electrode 9. In some embodiments, the light-emitting chip may further include a third connection electrode 14. One end (the left end as shown in FIG. 10) of the third connection electrode 14 is in lap joint with the third semiconductor sub-layer 221, and the other end (the right end as shown in FIG. 10) of the third connection electrode is in lap joint with the second semiconductor sub-layer 212, so as to realize the series connection between two light-emitting sub-chips. The other light-emitting electrode 9 (the light-emitting electrode 9 on the right side in FIG. 10) may be electrically connected to the fourth semiconductor sub-layer 222 through an eighth via hole K32, so as to lead out the fourth semiconductor sub-layer 222 through the other light-emitting electrode 9.

In some embodiments, for the light-emitting chip shown in FIGS. 6 to 10, the light-emitting chip is a light-emitting chip emitting blue light or green light. The first semiconductor layer 21 is the N-type semiconductor layer, and the second semiconductor layer 22 is the P-type semiconductor layer. In the embodiment of the present disclosure, for the light-emitting chip emitting blue light or green light, during specific manufacturing, as shown in FIG. 7, a buffer layer 24, an N-type semiconductor layer (as the first semiconductor layer 21), a light-emitting layer 23, and a P-type semiconductor layer (as the second semiconductor layer 22) may be sequentially formed on the substrate 1. The process of sequentially forming the buffer layer 24, the N-type semiconductor layer (as the first semiconductor layer 21), the light-emitting layer 23, and the P-type semiconductor layer (as the second semiconductor layer 22) on the substrate 1 is performed in a high-temperature environment. If the N-type semiconductor layer (as the first semiconductor layer 21) or the light-emitting layer 23 is required to be etched and thinned, the substrate 1 is required to be taken out of the high-temperature environment, and then enters the high-temperature environment to continue the subsequent processes after etching is completed, so that the problem that it is difficult to control the thermal stress and the temperature to be consistent is caused. If an area of the P-type semiconductor layer (as the second semiconductor layer 22) is required to be reduced, the P-type semiconductor layer (as the second semiconductor layer 22) has a small thickness (for example, only about 0.4 um), which is not sufficient to form the raised portion 30 having a visible height. Therefore, it is impossible to form the raised portion 30 of the light-emitting chip emitting blue light or green light in the same manner as the raised portion 30 of the light-emitting chip emitting red light.

Based on the same inventive concept, an embodiment of the present disclosure further provides a light-emitting substrate. As shown in FIG. 11, the light-emitting substrate includes the light-emitting chip according to the embodiment of the present disclosure and further includes a circuit substrate, the circuit substrate including: a circuit substrate 5, and a conductive layer 6, a circuit insulation layer 7, and a plurality of sub-substrate pads 8 sequentially positioned on one side of the circuit substrate 5, the sub-substrate pads 8 being soldered to sub-light-emitting auxiliary bonding layers 40 in a one-to-one corresponding manner. The soldered sub-light-emitting auxiliary bonding layers 40 serves as a light-emitting sub-pad 4.

In some embodiments, as shown in FIG. 11, the circuit substrate is provided with a substrate bulge 70 between adjacent sub-substrate pads 8, the substrate bulge 70 making contact with a raised portion 30.

In some embodiments, as shown in FIG. 11, the circuit substrate is provided with a recessed region 71 in a region where the sub-substrate pad 8 is positioned.

Based on the same inventive concept, an embodiment of the present disclosure further provides a display device. The display device includes the light-emitting substrate according to the embodiment of the present disclosure.

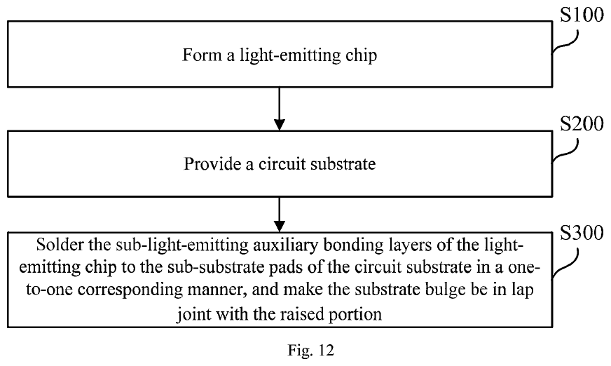

Based on the same inventive concept, an embodiment of the present disclosure further provides a manufacturing method for the light-emitting substrate according to the embodiment of the present disclosure. As shown in FIG. 12, the manufacturing method includes:
Step S100, a light-emitting chip is formed, the light-emitting chip including a plurality of sub-light-emitting auxiliary bonding layers and a raised portion located between adjacent sub-light-emitting auxiliary bonding layers;
Step S200, a circuit substrate is provided, the circuit substrate including a plurality of sub-substrate pads and a substrate bulge located between adjacent sub-substrate pads; and
Step S300, sub-light-emitting auxiliary bonding layers of the light-emitting chip are soldered to sub-substrate pads of the circuit substrate in a one-to-one corresponding manner, and the substrate bulge is in lap joint with the raised portion.

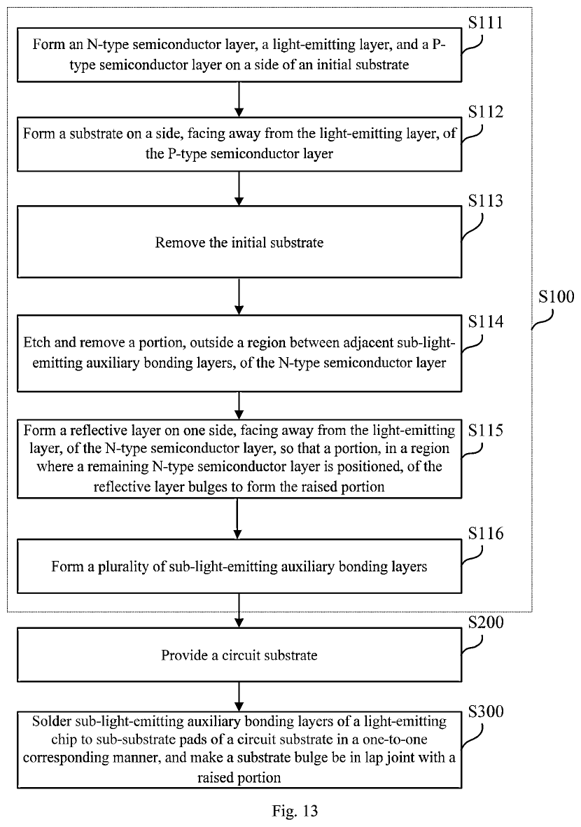

In some embodiments, as shown in FIG. 13, the step S100 that a light-emitting chip is formed includes:
Step S111, an N-type semiconductor layer, a light-emitting layer, and a P-type semiconductor layer are formed on a side of an initial substrate;
Step S112, a substrate is formed on a side, facing away from the light-emitting layer, of the P-type semiconductor layer;
Step S113, the initial substrate is removed;
Step S114, a portion, outside a region between adjacent sub-light-emitting auxiliary bonding layers, of the N-type semiconductor layer is etched and removed;
Step S115, a reflective layer is formed on a side, facing away from the light-emitting layer, of the N-type semiconductor layer, so that the reflective layer bulges in a region where a remaining P-type semiconductor layer is located, to form the raised portion; and
Step S116, a plurality of sub-light-emitting auxiliary bonding layers are formed.

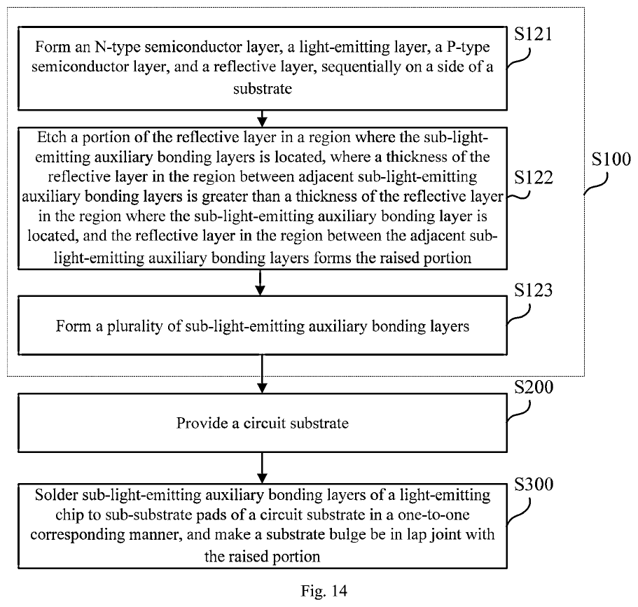

In some embodiments, as shown in FIG. 14, the step S100 that a light-emitting chip is formed includes:
Step S121, an N-type semiconductor layer, a light-emitting layer, a P-type semiconductor layer, and a reflective layer are sequentially formed on a side of a substrate;
Step S122, a portion, in a region where the sub-light-emitting auxiliary bonding layers is positioned, of the reflective layer is etched, where a thickness of the reflective layer in the region between adjacent sub-light-emitting auxiliary bonding layers is greater than a thickness of the reflective layer in the region where the sub-light-emitting auxiliary bonding layer is located, and the reflective layer in the region between the adjacent sub-light-emitting auxiliary bonding layers forms the raised portion; and
Step S123, a plurality of sub-light-emitting auxiliary bonding layers are formed.

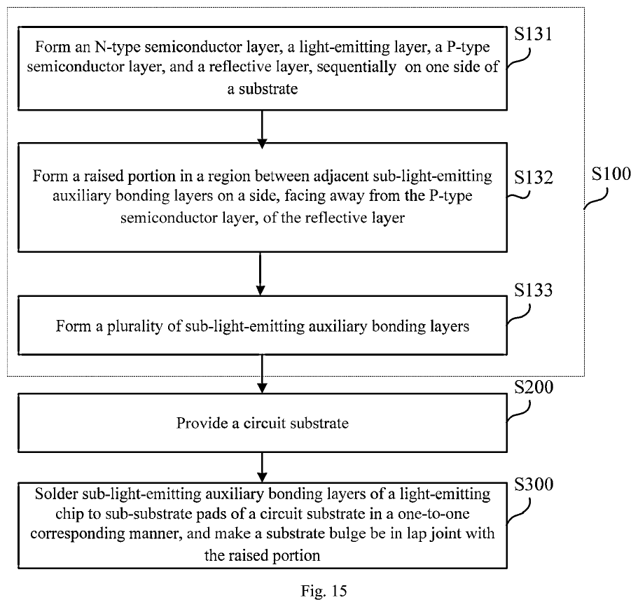

In some embodiments, as shown in FIG. 15, the step S100 that a light-emitting chip is formed includes:
Step S131, an N-type semiconductor layer, a light-emitting layer, a P-type semiconductor layer, and a reflective layer are sequentially formed on a side of a substrate;
Step S132, the raised portion is formed in a region between adjacent sub-light-emitting auxiliary bonding layers on a side, facing away from the P-type semiconductor layer, of the reflective layer; and
Step S133, a plurality of sub-light-emitting auxiliary bonding layers are formed.

In order to clearly understand the manufacturing method for the light-emitting substrate according to the embodiment of the present disclosure, the following is described in combination with the embodiment.

In some embodiments, when the light-emitting chip emits red light, as shown in FIGS. 16A to 16I, the method includes the following steps:
Step 1, an N-type semiconductor layer (as a second semiconductor layer 22), a light-emitting layer 23, and a P-type semiconductor layer (as a first semiconductor layer 21) are sequentially formed on a side of an initial substrate 10, as shown in FIGS. 16A to 16C;
Step 2, a substrate 1 is formed on a side, facing away from the light-emitting layer 23, of the P-type semiconductor layer (as the first semiconductor layer 21), as shown in FIG. 16D;
Step 3, the initial substrate 10 is removed, as shown in 16E;
Step 4, a portion, outside a region between adjacent sub-light-emitting auxiliary bonding layers, of the N-type semiconductor layer (as the second semiconductor layer 22) is etched and removed, as shown in FIG. 16F, where an area of the N-type semiconductor layer is reduced through etching, the N-type semiconductor layer may have a thickness range of 2 um-6 um, and in order to accurately control a thickness of a solder joint, the thickness of the N-type semiconductor layer is required to be accurately controlled at 4 um or so;
Step 5, a reflective layer 3 is formed on a side, facing away from the light-emitting layer 23, of the N-type semiconductor layer (as the second semiconductor layer 22), so that a portion, in a region where a remaining P-type semiconductor layer is positioned, of the reflective layer 3 bulges to form a raised portion 30, as shown in FIG. 16G; and
Step 6, a plurality of sub-light-emitting auxiliary bonding layers 40 are formed, as shown in FIG. 16H; and
Step 7: the sub-light-emitting auxiliary bonding layers 40 of the light-emitting chip are soldered to sub-substrate pads 8 of a circuit substrate in a one-to-one corresponding manner, and a substrate bulge 70 is in lap joint with the raised portion 30, as shown in FIG. 16I.

A curve shown in FIG. 16J is a curve of an ABC model of an internal quantum efficiency of a light-emitting diode (LED), a formula of which is

$${η}_{IQE} = {η}_{INJ} \frac{{BN}^{2}}{AN + {BN}^{2} + {CN}^{3}} ,$$

where η_{IQE} is the internal quantum efficiency, η_{INJ} is a carrier injection efficiency, A, B, and C are three constants, A is (10⁷-10⁸) mainly related to non-radiative recombination (mainly determined by defects), B is (10⁻¹⁰-10⁻¹²) mainly related to radiative recombination, C is (10⁻³⁰) mainly related to Auger recombination, and N is the number of carriers. It can be seen that N is small under a small current, and the efficiency of a light-emitting diode chip is mainly determined by the non-radiative recombination. In order to reduce the fluctuation caused by defects, the light-emitting diode chip is required to work at a position with a large N as much as possible, that is, to work in a high-current density range. In the embodiment of the present disclosure, after the area of the N-type semiconductor layer is reduced, a current density under a small current may be increased through the above theoretical formula, and the entire uniformity may be improved.

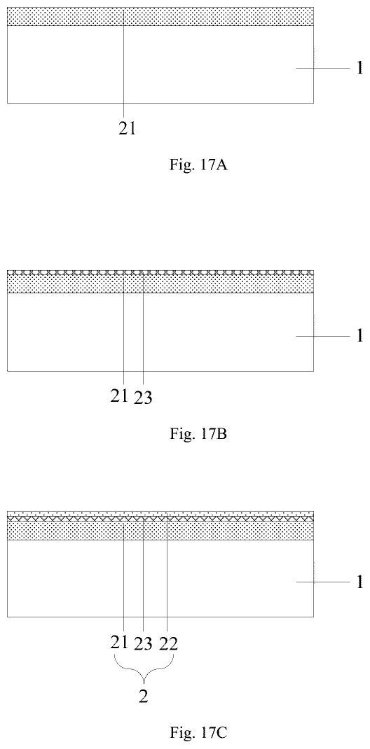

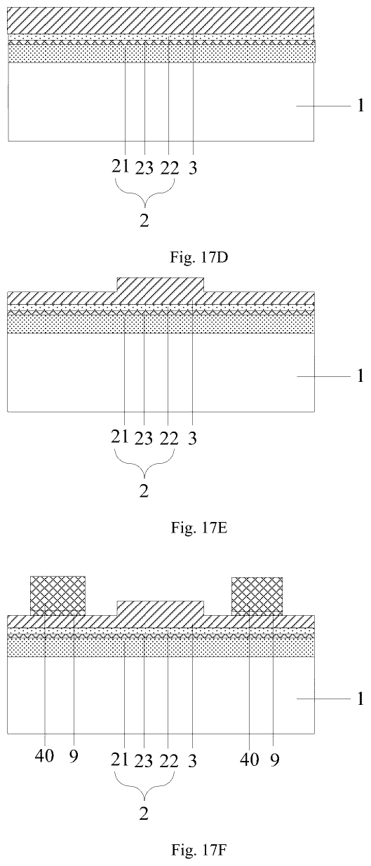

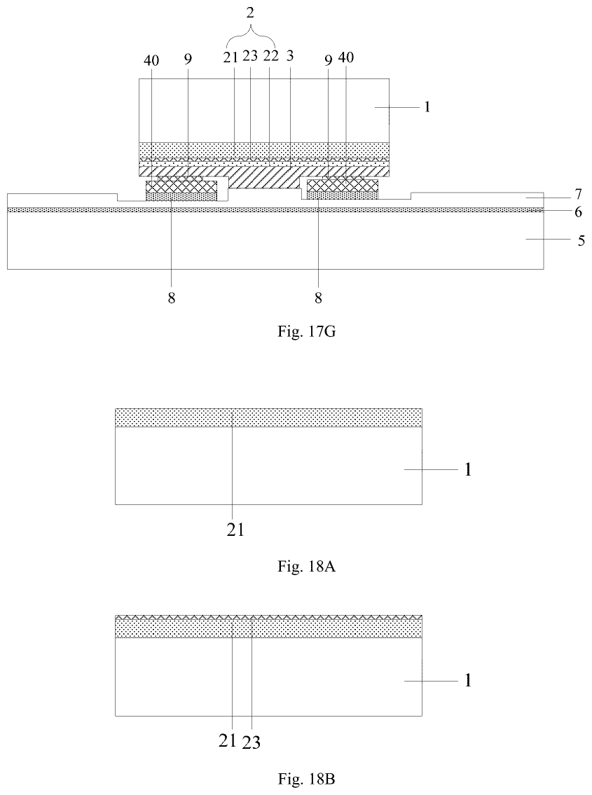

In some embodiments, when the light-emitting chip is a light-emitting chip emitting blue light or green light, as shown in FIGS. 17A to 17G, the method includes the following steps:
Step 1, an N-type semiconductor layer (as a first semiconductor layer 21), a light-emitting layer 23, a P-type semiconductor layer (as a second semiconductor layer 22), and a reflective layer 3 are sequentially formed on one side of a substrate 1, as shown in FIGS. 17A to 17D;
Step 2, a portion, in a region where a sub-light-emitting auxiliary bonding layers 40 is positioned, of the reflective layer 3 is etched, so that a portion, in a region between adjacent sub-light-emitting auxiliary bonding layers 40, of the reflective layer 3 has a greater thickness than the portion, in the region where the sub-light-emitting auxiliary bonding layers is positioned, of the reflective layer, and a raised portion is formed in the portion, in the region between adjacent sub-light-emitting auxiliary bonding layers 40, of the reflective layer 3, as shown in 17E;
Step 3, a plurality of sub-light-emitting auxiliary bonding layers 40 are formed, as shown in FIG. 17F; and
Step 4, the sub-light-emitting auxiliary bonding layers 40 of the light-emitting chip are soldered to sub-substrate pads 8 of a circuit substrate in a one-to-one corresponding manner, and a substrate bulge 70 is in lap joint with the raised portion 30, as shown in FIG. 17G.

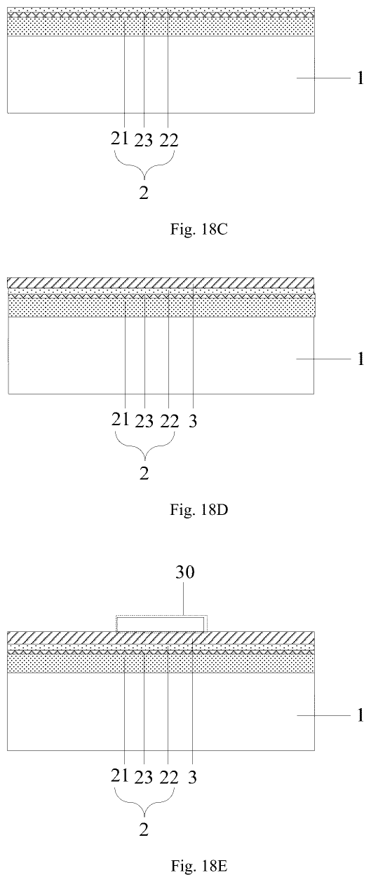

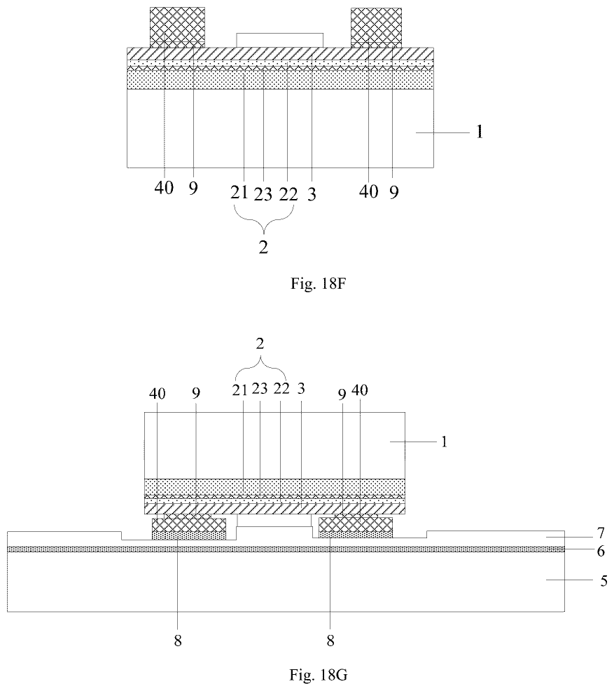

In some embodiments, when the light-emitting chip is a light-emitting chip emitting blue light or green light, as shown in FIGS. 17A to 17G, the method includes the following steps:
Step 1, an N-type semiconductor layer (as a first semiconductor layer 21), a light-emitting layer 23, a P-type semiconductor layer (as a second semiconductor layer 22), and a reflective layer 3 are sequentially formed on one side of a substrate 1, as shown in FIGS. 18A to 18D;
Step 2, a raised portion is formed in a region between adjacent sub-light-emitting auxiliary bonding layers 40 on one side, facing away from the P-type semiconductor layer (as the second semiconductor layer 22), of the reflective layer, as shown in 18E;
Step 3, a plurality of sub-light-emitting auxiliary bonding layers 40 are formed, as shown in FIG. 18F; and
Step 4, the sub-light-emitting auxiliary bonding layers 40 of the light-emitting chip are soldered to sub-substrate pads 8 of a circuit substrate in a one-to-one corresponding manner, and a substrate bulge 70 is in lap joint with the raised portion 30, as shown in FIG. 18G.

In the embodiment of the present disclosure, the light-emitting chip includes the raised portion 30, the orthographic projection, on the substrate 1, of the raised portion 30 not overlapping the orthographic projection, on the substrate 1, of the sub-light-emitting auxiliary bonding layers 40, and the thickness d1 of the raised portion 30 being smaller than the thickness d2 of the sub-light-emitting auxiliary bonding layers 40. When the light-emitting chip is soldered to the circuit substrate, the raised portion 30 may be in lap joint with the circuit substrate to fix the distance between the light-emitting chip and the circuit substrate. Therefore, the final thickness of the solder joint may be controlled, and the fixed thickness of the solder joint may increase the tension when the sub-light-emitting auxiliary bonding layers 40 is melted, so that the solder formed by melting the sub-light-emitting auxiliary bonding layers 40 is continuously and uniformly stretched, thereby increasing a soldering yield of the light-emitting chip and the circuit substrate. If the light-emitting chip is soldered to the circuit substrate poorly, the raised portion 30 is arranged to form the large distance between the light-emitting chip and the circuit substrate, so that the damage to the sub-substrate pad 8 is avoided when the light-emitting chip is separated from the circuit substrate, and a repair yield may also be increased. Moreover, since the raised portion 30 exists between the sub-light-emitting auxiliary bonding layers 40, the problem that the light-emitting chip fails due to the fact that different sub-light-emitting auxiliary bonding layers 40 are electrically connected during soldering when the distance between the sub-light-emitting auxiliary bonding layers 40 is small may be prevented. In addition, considering that the area of the sub-substrate pad will be correspondingly expanded in actual use, so as to adapt to the design of the mini light-emitting diodes and/or the micro light-emitting diodes with different size. For the small-sized mini light-emitting diode and/or micro light-emitting diode, the sub-light-emitting auxiliary bonding layers 40 is small and spreads over the sub-substrate pad with a large area after reflow, and the thickness of the solder joint will be correspondingly reduced. If the raised portion 30 in the embodiment of the present disclosure is provided, the thickness of the solder joint will not be reduced excessively. Therefore, in one aspect, the requirement on the amount of the solder and the area accuracy of the sub-substrate pad may be reduced, and in another aspect, the sub-substrate pad with the same size may be adapted to mini light-emitting diodes and/or micro light-emitting diodes with various specifications, so that the compatibility is high.

Obviously, those skilled in the art can make various amendments and variations to the embodiments of the present disclosure, without departing from the spirit and scope of the embodiments of the present disclosure. In this way, it is intended that the present disclosure is also intended to encompass these amendments and variations if these amendments and variations to the embodiments of the present disclosure fall within the scope of the claims of the present disclosure and the equivalents thereof.

1. A light-emitting chip, comprising:
a substrate;
a light-emitting structure, the light-emitting structure disposed on a side of the substrate;
a reflective layer, the reflective layer disposed on a side, facing away from the substrate, of the light-emitting structure;
at least two sub-light-emitting auxiliary bonding layers, the at least two sub-light-emitting auxiliary bonding layers disposed on a side, facing away from the light-emitting structure, of the reflective layer; and
a raised portion, the raised portion disposed on a side, facing away from the light-emitting structure, of the reflective layer;
wherein an orthographic projection of the raised portion on the substrate and an orthographic projection of the at least two sub-light-emitting auxiliary bonding layers on the substrate do not overlap with each other; and
a thickness of the raised portion is smaller than a thickness of each of the at least two sub-light-emitting auxiliary bonding layers.

2. The light-emitting chip according to claim 1, wherein the light-emitting structure comprises a first semiconductor layer, a light-emitting layer, and a second semiconductor layer;
the first semiconductor layer, the light-emitting layer, and the second semiconductor layer are sequentially stacked on a side of the substrate; and
an orthographic projection, on the substrate, of at least one of the first semiconductor layer, the light-emitting layer, and the second semiconductor layer substantially approximately overlaps with an orthographic projection, on the substrate, of the raised portion, so as to form the raised portion.

3. The light-emitting chip according to claim 2, wherein a thickness of the reflective layer in a region where the raised portion is located is approximately equal to a thickness of the reflective layer in a region where the sub-light-emitting auxiliary bonding layers is located.

4. The light-emitting chip according to claim 2, wherein the light-emitting chip is a light-emitting chip emitting red light;
the first semiconductor layer is a P-type semiconductor layer; and
the second semiconductor layer is an N-type semiconductor layer;
wherein the raised portion of the light-emitting chip is formed by the second semiconductor layer.

5. The light-emitting chip according to claim 1, wherein a thickness of the reflective layer in the region where the raised portion is located is greater than a thickness of the reflective layer in the region where the sub-light-emitting auxiliary bonding layer is located, so as to form the raised portion by thickening the region, where the raised portion is positioned, of the reflective layer.

6. The light-emitting chip according to claim 5, wherein the raised portion and the reflective layer are of an integrated structure; and the raised portion is made of a same material as the reflective layer.

7. The light-emitting chip according to claim 1, wherein the raised portion and the reflective layer are of structures independent of each other, and the raised portion is made of a different material from the reflective layer.

8. The light-emitting chip according to claim 2, wherein the light-emitting chip is a light-emitting chip emitting blue light or green light; and
the first semiconductor layer is an N-type semiconductor layer, and the second semiconductor layer is a P-type semiconductor layer.

9. A light-emitting substrate, comprising the light-emitting chip according to claim 1, and further comprising a circuit substrate;
wherein the circuit substrate comprises a plurality of sub-substrate pads, and the sub-substrate pads are soldered to the sub-light-emitting auxiliary bonding layers in a one-to-one corresponding manner.

10. The light-emitting substrate according to claim 9, wherein the circuit substrate is provided with a substrate bulge between adjacent sub-substrate pads, the substrate bulge making contact with the raised portion.

11. The light-emitting substrate according to claim 9, wherein the circuit substrate is provided with a plurality of recessed regions in regions where the sub-substrate pads are located.

12. A display device, comprising the light-emitting substrate according to claim 9.

13. A manufacturing method for the light-emitting substrate according to claim 9, comprising:
forming the light-emitting chip, the light-emitting chip comprising the plurality of sub-light-emitting auxiliary bonding layers and the raised portion located between adjacent sub-light-emitting auxiliary bonding layers;
providing the circuit substrate, the circuit substrate comprising the plurality of sub-substrate pads and the substrate bulge located between adjacent sub-substrate pads; and
soldering the sub-light-emitting auxiliary bonding layers of the light-emitting chip to the sub-substrate pads of the circuit substrate in a one-to-one corresponding manner, and making the substrate bulge be in lap joint with the raised portion.

14. The manufacturing method according to claim 13, wherein the forming the light-emitting chip comprises:
forming an N-type semiconductor layer, a light-emitting layer, and a P-type semiconductor layer on a side of an initial substrate;
forming the substrate on a side, facing away from the light-emitting layer, of the P-type semiconductor layer;
removing the initial substrate;
etching and removing a portion, outside a region between adjacent sub-light-emitting auxiliary bonding layers, of the P-type semiconductor layer;
forming the reflective layer on a side, facing away from the light-emitting layer, of the P-type semiconductor layer, so that the reflective layer bulges in a region where a remaining P-type semiconductor layer is located, to form the raised portion; and
forming the plurality of sub-light-emitting auxiliary bonding layers.

15. The manufacturing method according to claim 13, wherein the forming the light-emitting chip comprises:
forming an N-type semiconductor layer, a light-emitting layer, a P-type semiconductor layer, and a reflective layer, sequentially on a side of the substrate;
etching a portion of the reflective layer in a region where the sub-light-emitting auxiliary bonding layers is located, wherein a thickness of the reflective layer in the region between adjacent sub-light-emitting auxiliary bonding layers is greater than a thickness of the reflective layer in the region where the sub-light-emitting auxiliary bonding layer is located, and the reflective layer in the region between the adjacent sub-light-emitting auxiliary bonding layers forms the raised portion; and
forming the plurality of sub-light-emitting auxiliary bonding layers.

16. The manufacturing method according to claim 13, wherein the forming the light-emitting chip comprises:
forming an N-type semiconductor layer, a light-emitting layer, a P-type semiconductor layer, and a reflective layer, sequentially on a side of the substrate;
forming the raised portion in a region between adjacent sub-light-emitting auxiliary bonding layers on a side, facing away from the P-type semiconductor layer, of the reflective layer; and
forming the plurality of sub-light-emitting auxiliary bonding layers.

17. The light-emitting substrate according to claim 9, wherein the light-emitting structure comprises a first semiconductor layer, a light-emitting layer, and a second semiconductor layer;
the first semiconductor layer, the light-emitting layer, and the second semiconductor layer are sequentially stacked on a side of the substrate; and
an orthographic projection, on the substrate, of at least one of the first semiconductor layer, the light-emitting layer, and the second semiconductor layer substantially approximately overlaps with an orthographic projection, on the substrate, of the raised portion, so as to form the raised portion.

18. The light-emitting substrate according to claim 17, wherein a thickness of the reflective layer in a region where the raised portion is located is approximately equal to a thickness of the reflective layer in a region where the sub-light-emitting auxiliary bonding layers is located.

19. The light-emitting substrate according to claim 17, wherein the light-emitting chip is a light-emitting chip emitting red light;
the first semiconductor layer is a P-type semiconductor layer; and
the second semiconductor layer is an N-type semiconductor layer;
wherein the raised portion of the light-emitting chip is formed by the second semiconductor layer.

20. The light-emitting substrate according to claim 9, wherein a thickness of the reflective layer in the region where the raised portion is located is greater than a thickness of the reflective layer in the region where the sub-light-emitting auxiliary bonding layer is located, so as to form the raised portion by thickening the region, where the raised portion is positioned, of the reflective layer.
